(19) United States
(12) Patent Application Publication
(10) Pub. No.: US 2023/0087100 A1
(43) Pub. Date: Mar. 23, 2023

(54) PULSE-BASED QUANTUM GATE IMPLEMENTATION

(71) Applicant: Beijing Baidu Netcom Science Technology Co., Ltd., Beijing (CN)

(72) Inventors: Zelin Meng, Beijing (CN); Xin Wang, Beijing (CN); Lijing Jin, Beijing (CN); Qinghe Wang, Beijing (CN)

(73) Assignee: Beijing Baidu Netcom Science Technology Co., Ltd., Beijing (CN)

(21) Appl. No.: 17/943,982

(22) Filed: Sep. 13, 2022

(30) Foreign Application Priority Data
Sep. 17, 2021 (CN) 202111093659

(51) Int. Cl. G06N 10/20; H03K 19/195

(52) U.S. Cl. CPC G06N 10/20; H03K 19/195

(57) ABSTRACT

A method is provided. The method includes determining a corresponding relationship between a pulse enveloping parameter and a single pulse duration, and determining a parameter to be optimized; and determining a maximum pulse number, an initialized current pulse number and a preset error tolerance. The method further includes executing an iterative operation including determining a quantum gate matrix to be implemented and a value of a loss function based on the current pulse number and the parameter to be optimized; adjusting a group of parameter values of the parameter to be optimized to minimize the value of the loss function; determining an error with a target quantum gate matrix after the value of the loss function is minimized; and in response to that the current pulse number is less than the maximum pulse number and the error is greater than the error tolerance, adding one to the current pulse number.

### CROSS REFERENCE TO RELATED APPLICATIONS

The present application claims priority to Chinese Patent Application No. 202111093659.2 filed on Sep. 17, 2021, the content of which is hereby incorporated by reference in its entirety for all purposes.

### TECHNICAL FIELD

The present disclosure relates to the field of quantum computers, particularly relates to the technical field of quantum gates and pulse control, and specifically relates to a pulse-based quantum gate implementation method and apparatus, an electronic device, a computer readable storage medium and a computer program product.

### BACKGROUND

In the field of quantum control, in a process of compiling a quantum logic gate at the level of quantum software into a physical pulse signal that can be identified by quantum hardware, it may be interfered by many non-ideal factors (such as high energy level leakage, crosstalk, etc.). Therefore, the physical pulse signal needs to be reasonably designed to restrain and even eliminate the influence of the non-ideal factors so as to improve fidelity of a quantum gate.

### SUMMARY

The present disclosure provides a pulse-based quantum gate implementation method and apparatus, an electronic device, a computer readable storage medium and a computer program product.

According to one aspect of the present disclosure, a pulse-based quantum gate implementation method is provided, including: determining a corresponding relationship between a pulse enveloping parameter and a single pulse duration, and determining a parameter to be optimized based on the corresponding relationship; determining a maximum pulse number, an initialized current pulse number and a preset error tolerance, wherein the initialized current pulse number is less than the maximum pulse number; executing an iterative operation, until a pulse number reaches the maximum pulse number or an error of a quantum gate to be implemented is not greater than the error tolerance. The iterative operation includes obtaining, based on the current pulse number, a group of parameter values of the parameter to be optimized, wherein the group of parameter values corresponds to the current pulse number; determining a quantum gate matrix to be implemented based on the current pulse number and the group of parameter values; determining a value of a loss function based on the quantum gate matrix to be implemented and a target quantum gate matrix; adjusting the group of parameter values of the parameter to be optimized to minimize the value of the loss function; determining a quantum gate matrix to be implemented obtained after minimizing the value of the loss function and calculating an error between the quantum gate matrix to be implemented and the target quantum gate matrix; and in response to determining that the current pulse number is less than the maximum pulse number and the error is greater than the error tolerance, adding one to the current pulse number; and based on the current pulse number and the group of parameter values of the parameter to be optimized obtained after the iterative operation, generating a corresponding pulse to implement a quantum gate.

According to another aspect of the present disclosure, an electronic device is provided, including: a memory storing one or more programs configured to be executed by one or more processors, the one or more programs including instructions for causing the electronic device to perform operations comprising: determining a corresponding relationship between a pulse enveloping parameter and a single pulse duration, and determining a parameter to be optimized based on the corresponding relationship; determining a maximum pulse number, an initialized current pulse number and a preset error tolerance, wherein the initialized current pulse number is less than the maximum pulse number; executing an iterative operation until a pulse number reaches the maximum pulse number or an error of a quantum gate to be implemented is not greater than the preset error tolerance, the iterative operation including: obtaining, based on the current pulse number, a group of parameter values of the parameter to be optimized, wherein the group of parameter values corresponding to the current pulse number; determining a quantum gate matrix to be implemented based on the current pulse number and the group of parameter values; determining a value of a loss function based on the quantum gate matrix to be implemented and a target quantum gate matrix; adjusting the group of parameter values of the parameter to be optimized to minimize the value of the loss function; determining a quantum gate matrix to be implemented obtained after minimizing the value of the loss function and calculating an error between the quantum gate matrix to be implemented and the target quantum gate matrix; and in response to determining that the current pulse number is less than the maximum pulse number and the error is greater than the error tolerance, adding one to the current pulse number; and based on the current pulse number and the group of parameter values of the parameter to be optimized obtained after the iterative operation, generating a corresponding pulse to implement a quantum gate.

According to another aspect of the present disclosure, a non-transitory computer readable storage medium that stores one or more programs comprising instructions that, when executed by one or more processors of a computing device, cause the computing device to implement operations comprising: determining a corresponding relationship between a pulse enveloping parameter and a single pulse duration, and determining a parameter to be optimized based on the corresponding relationship; determining a maximum pulse number, an initialized current pulse number and a preset error tolerance, wherein the initialized current pulse number is less than the maximum pulse number; executing an iterative operation until a pulse number reaches the maximum pulse number or an error of a quantum gate to be implemented is not greater than the preset error tolerance, the iterative operation including: obtaining, based on the current pulse number, a group of parameter values of the parameter to be optimized, wherein the group of parameter values corresponding to the current pulse number; determining a quantum gate matrix to be implemented based on the current pulse number and the group of parameter values; determining a value of a loss function based on the quantum gate matrix to be implemented and a target quantum gate matrix; adjusting the group of parameter values of the parameter to be optimized to minimize the value of the loss function; determining a quantum gate matrix to be implemented obtained after minimizing the value of the loss function and calculating an error between the quantum gate matrix to be implemented and the target quantum gate matrix; and in response to determining that the current pulse number is less than the maximum pulse number and the error is greater than the error tolerance, adding one to the current pulse number; and based on the current pulse number and the group of parameter values of the parameter to be optimized obtained after the iterative operation, generating a corresponding pulse to implement a quantum gate.

It should be understood that the content described in this part is not intended to identify key or important features of the embodiments of the present disclosure, nor is it used to limit the scope of the present disclosure. Other features of the present disclosure will be easily understood by the following description.

### BRIEF DESCRIPTION OF THE DRAWINGS

The accompanying drawings illustrate embodiments by way of example and form part of the description, which, together with the textual description of the description, is used to explain example implementations of the embodiments. The illustrated embodiments are for illustrative purposes only and do not limit the scope of the claims. In all the drawings, the same reference numerals refer to similar but not necessarily identical elements.

FIG. 1 shows a flow diagram of a pulse-based quantum gate implementation method according to an embodiment of the present disclosure;

FIG. 2 shows a schematic diagram of a pulse circuit alternately generating pulses according to an embodiment of the present disclosure;

FIG. 3 shows a flow diagram of generating a corresponding pulse based on a group of parameter values obtained after optimization according to an embodiment of the present disclosure;

FIG. 4 shows a flow diagram of a pulse parameter determining method according to an embodiment of the present disclosure;

FIG. 5 shows a line chart of a corresponding relationship of a parameter C₁ and distortion according to an embodiment of the present disclosure;

FIG. 6 shows a line chart of a corresponding relationship of a parameter C₁ and a total pulse duration according to an embodiment of the present disclosure;

FIG. 7 shows a schematic diagram of a pulse sequence corresponding to a pulse parameter obtained after optimization according to an embodiment of the present disclosure;

FIG. 8 shows a structural block diagram of a pulse-based quantum gate implementation apparatus according to an embodiment of the present disclosure; and

FIG. 9 shows a structural block diagram of an exemplary electronic device capable of being used to implement an embodiment of the present disclosure.

### DETAILED DESCRIPTION

The exemplary embodiments of the present disclosure are described below in combination with the accompanying drawings, including various details of the embodiments of the present disclosure to facilitate understanding, which should be considered only exemplary. Therefore, those of ordinary skill in the art should recognize that various changes and modifications may be made to the embodiments described herein without departing from the scope of the present disclosure. Similarly, for clarity and conciseness, the description of well-known functions and structures is omitted from the following description.

In the present disclosure, unless otherwise specified, the terms “first”, “second” and the like are used to describe various elements and are not intended to limit the positional relationship, temporal relationship or importance relationship of these elements. These terms are only used to distinguish one element from another element. In some examples, a first element and a second element may point to the same instance of the element, and in some cases, based on the context description, they can also refer to different instances.

The terms used in the description of the various examples in the present disclosure are only for the purpose of describing specific examples and are not intended to be limiting. Unless the context clearly indicates otherwise, if the number of elements is not specifically limited, the element may be one or more. In addition, the term “and/or” as used in the present disclosure covers any and all possible combinations of the listed items.

The embodiments of the present disclosure will be described in detail below in combination with the accompanying drawings.

So far, various different types of computers in application all take classical physics as a theoretical basis for information processing, and are called traditional computers or classical computers. A classical information system uses binary data bits that are physically the easiest to implement to store data or programs, and each binary data bit is represented by 0 or 1, which is called a bit as the smallest information unit. There are inevitable weaknesses in the classical computers: first, the most basic limitation of energy consumption in a computing process. The minimum energy required by logic elements or storage units shall be more than several times of kT (where k represents the Boltzmann constant and T represents the temperature) to avoid misoperation during thermal fluctuation; second, information entropy and heating energy consumption; and third, when the wiring density of a computer chip is very large, according to the Heisenberg uncertainty relationship, the uncertainty of momentum will be very large when the uncertainty of an electron position is very small. When electrons are no longer bound, there will be a quantum interference effect, which will even destroy the performance of the chip.

A quantum computer is a kind of physical device that follows the properties and laws of quantum mechanics to carry out high-speed mathematical and logical operations, and store and process quantum information. When a certain device processes and computes quantum information and runs a quantum algorithm, it is a quantum computer. The quantum computer follows the unique law of quantum dynamics (especially quantum interference) to realize a new mode of information processing. For parallel processing of computing problems, the quantum computer has absolute advantages in speed compared with the classical computers. The transformation of each superposition component realized by the quantum computer is equivalent to a classical computation, and all these classical computations are completed at the same time and superimposed according to a certain probability amplitude to give an output result of the quantum computer. This computation is called quantum parallel computation. Quantum parallel processing greatly improves the efficiency of the quantum computer, so that it can complete the work that the classical computers can not complete, such as factorization of a very large natural number. Quantum coherence is essentially utilized in all quantum ultrafast algorithms. Therefore, quantum parallel computation using quantum states instead of classical states can achieve the incomparable operation speed and information processing function of the classical computers, and save a lot of operation resources at the same time.

Quantum control is not only a bridge connecting quantum software and hardware, but also an indispensable link in quantum computation. In quantum computation, in addition to concerning about the performance of quantum hardware (including the quality and quantity of quantum bits), how to effectively control the quantum hardware further needs to be considered, so as to make quantum tasks executed efficiently. Specifically, a quantum logic gate at the level of quantum software needs to be compiled into a physical pulse signal that can be identified by the quantum hardware.

At present, there are several quantum hardware candidates in the industry. Benefiting from the advantages of long coherence time, easy expansion and the like of quantum bits, a superconducting circuit has made great development in recent years. Moreover, many valuable quantum tasks have been realized and verified in a superconducting platform. However, in a practical superconducting circuit, there are many non-ideal factors (such as high energy level leakage, crosstalk, etc.) that limit the fidelity of a real quantum gate. To solve this problem, researchers usually design reasonable pulses to suppress or even eliminate their influences, so as to greatly improve the fidelity of the quantum gate. A common technical solution is that researchers perform simulation and optimization by establishing a physical model, calculate a group of pulse parameters, and then perform pulse calibration in a real quantum hardware system to further improve the fidelity. Limited by the coherence time of the quantum bits, if the quantum gate time is too long, it will have a great impact on the efficiency and effectiveness of a whole quantum control system. In addition to the pulse time, a quantum gate pulse which can produce high fidelity under the influence of environmental noise is also an important index to measure a pulse technical solution.

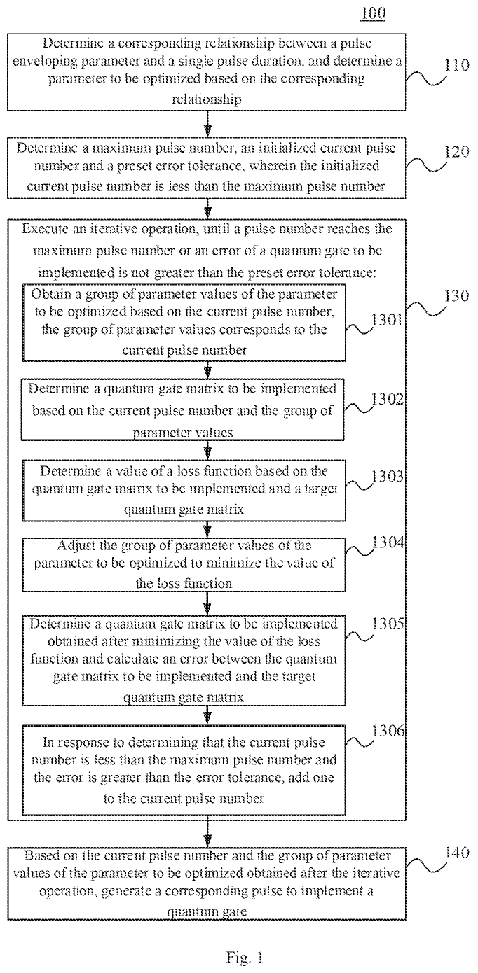

Therefore, a pulse-based quantum gate implementation method is provided according to an embodiment of the present disclosure. FIG. 1 shows a flow diagram 100 of a pulse-based quantum gate implementation method according to an embodiment of the present disclosure. As shown in FIG. 1, the method includes steps to: determine a corresponding relationship between a pulse enveloping parameter and a single pulse duration, and determine a parameter to be optimized based on the corresponding relationship (step 110); determine a maximum pulse number, an initialized current pulse number and a preset error tolerance, wherein the initialized current pulse number is less than the maximum pulse number (step 120); an iterative operation is executed, until a pulse number reaches the maximum pulse number or an error of a quantum gate to be implemented is not greater than the error tolerance (step 130): obtain a group of parameter values of the parameter to be optimized based on the current pulse number, wherein the group of parameter values corresponds to the current pulse number (step 1301); determine a quantum gate matrix to be implemented based on the current pulse number and the group of parameter values (step 1302); determine a value of a loss function based on the quantum gate matrix to be implemented and a target quantum gate matrix (step 1303); and adjust the group of parameter values of the parameter to be optimized to minimize the value of the loss function (step 1304); determine a quantum gate matrix to be implemented obtained after minimizing the value of the loss function and calculate an error between the quantum gate matrix to be implemented and the target quantum gate matrix (step 1305); and in response to determining that the current pulse number is less than the maximum pulse number and the error is greater than the error tolerance, add one to the current pulse number (step 1306); and based on the current pulse number and the group of parameter values of the parameter to be optimized obtained after the iterative operation, generate a corresponding pulse to implement a quantum gate (step 140).

According to the embodiment of the present disclosure, a pulse duration is considered in an optimization process, so that a pulse shape is effectively constrained, it is friendlier to hardware, and the difficulty of pulse generation in a real quantum computer is reduced.

In an experiment of quantum computation, some simulations and emulations are usually performed prior to the experiment. In this process, a quantum system needs to be modeled, and an evolution result of the system at any moment is obtained by solving a Schrodinger equation. In quantum optimization control, a core objective is designing control items of the system to make a time sequence evolution operator of the system after time t close to a matrix of a target quantum gate as far as possible. Therefore, the embodiment of the method according to the present disclosure may be described by taking a simulation and emulation process as an example.

The quantum gate matrix to be implemented according to the present disclosure is a matrix of a quantum gate required to be generated according to the optimized pulse parameter, namely, a matrix form of a real quantum gate.

In some embodiments, an example that pulses are applied to X-Y channels with three-energy-level superconducting quantum bits to realize a single-bit quantum gate is taken for description. It can be understood that it is similar in the case of other energy level systems and other channel numbers (e.g., an X channel only, or three channels of X-Y-Z) in the system, which is not repeated here.

Under a representation of interaction, a Hamiltonian H(t) of the system may be expressed as a formula (1):

$$H ( t ) = \frac{{α}_{q}}{2} \vert 2 〉 〈 2 \vert + {\sum }_{k = 1}^{M} [ \frac{1}{2} {A}_{k}^{x} ( t ) ( {\hat{σ}}_{+} + {\hat{σ}}_{-} ) ] + {\sum }_{l = 1}^{N} [ \frac{i}{2} {A}_{l}^{y} ( t ) ( {\hat{σ}}_{+} - {\hat{σ}}_{-} ) ] \qquad Formula ( 1 )$$

In the formula (1), α_{q} represents discord intensity of the superconducting quantum bits; \hat{σ}=|1><0|+\sqrt{2}|2><| and \hat{σ}_=|0><1|+\sqrt{2}|1><2| are respectively a creation operator and an annihilation operator; in addition, |0>=[1,0,0]^{T}, |1>=[0,1,0]^{T} and |2>=[0,0,1]^{T}; Aₖ₍ₗ₎^{x(y)}(t) corresponds to a Gaussian envelope function of pulses of an X(Y) channel, where M(N) respectively represents the numbers of the pulses of the X(Y) channel, and k(l) respectively represents serial numbers of the pulses of the X(Y) channel; while Aₖ₍ₗ₎^{x(y)}(t) may be specifically expressed as a formula (2):

Aₖ₍ₗ₎^{x(y)}(t)=Aₖ₍ₗ₎^{x(y)}exp[((t−τₖ₍ₗ₎^{x(y)})/σₖ₍ₗ₎^{x(y)})²] Formula (2)

In the formula (2), Aₖ₍ₗ₎^{x(y)}, τₖ₍ₗ₎^{x(y)} and σₖ₍ₗ₎^{x(y)} are respectively parameters of Gaussian pulses of the X(Y) channel, and exp represents scalar exponent operation. After Hamiltonian of one system is obtained, all information of the system can be obtained, including time evolution information of the system.

Giving Hamiltonian H(t) of a quantum system, a kinetic equation that a time sequence evolution operator U(t) meets may be described with a schrodinger equation (i.e., a formula (3)):

$$i ℏ \frac{\partial }{\partial t} U ( t ) = H ( t ) U ( t ) \qquad Formula ( 3 )$$

where i is the imaginary unit, and h is the Planck constant. By solving the time-dependent differential equation, a time sequence evolution operator U(t) of the system at any moment can be obtained.

In the above embodiment of realizing the single-bit quantum gate, exemplarily, the target quantum gate matrix may be determined based on a formula (4):

$${U}_{Goal} ( θ , ϕ , λ ) = [ \begin{matrix}cos ( \frac{θ}{2} ) & - {e}^{i λ} sin ( \frac{θ}{2} ) \\ {e}^{i ϕ} sin ( \frac{θ}{2} ) & {e}^{i ( ϕ + λ )} cos ( \frac{θ}{2} )\end{matrix} ] \qquad Formula ( 4 )$$

where {θ, ϕ, λ} represent the parameters of the target quantum gate. That is, the operation of the single-quantum bit gate may be described through three parameters {θ, ϕ, λ}, that is, after the parameters {θ, ϕ, λ} are determined, the corresponding single quantum bit quantum gate can be determined according to the formula (4).

According to some embodiments, the loss function may be determined based on a formula (5):

$$g ( \overline{α} ) = 1 - \frac{1}{2} \vert Tr ( {U}_{Goal}^{†} {U}_{Real} ( \overline{α} ) ) \vert \qquad Formula ( 5 )$$

where α̅ represents a group of parameter values of the parameters to be optimized in the iterative operation, U_{Real}(α̅) represents the quantum gate matrix to be implemented, U_{Goal}^{†} represents an inverse of the target quantum gate matrix, and Tr( ) represents a trace of the matrix.

As described above, after one target quantum gate matrix U_{Goal}(θ, ϕ, λ) is determined, a difference between a real quantum gate generated by a current pulse parameter and the target quantum gate may be measured by using a target function (i.e., the loss function). Where α̅=[A₁₍₁₎^{x(y)} . . . A_{M(N)}^{x(y)}; τ₁₍₁₎^{x(y)} . . . τ_{M(N)}^{x(y)}; σ₁₍₁₎^{x(y)} . . . σ_{M(N)}^{x(y)}] is a pulse parameter vector to be optimized, U_{Real}(α̅) is a real quantum gate matrix obtained by using a pulse parameter a and by calculating the schrodinger equation (3), and Tr represents a trace of the matrix, namely a sum of diagonal elements of the matrix. Once the target function has been determined, an optimization algorithm can be used to minimize the target function to obtain the pulse parameters required for realizing a given quantum operation.

According to some embodiments, adjusting the group of parameter values of the parameters to be optimized to minimize the loss function includes: the group of parameter values of the parameters to be optimized is adjusted through the optimization algorithm to minimize the loss function. The optimization algorithm includes but not limited to: a gradient descent method, a Newton method, a conjugate gradient method, a heuristic method, and so on.

On a recent superconducting quantum bit platform, the performance of quantum bits is limited to their coherence time, so that it is desired that operation time of a quantum gate is as short as possible to reduce the impact of de-coherence as much as possible. However, in a typical pulse parameter optimization solution, a pulse parameter to be optimized: α̅=[A₁₍₁₎^{x(y)} . . . A_{M(N)}^{x(y)}; τ₁₍₁₎^{x(y)} . . . τ_{M(N)}^{x(y)}; σ₁₍₁₎^{x(y)} . . . σ_{M(N)}^{x(y)}] is mainly a parameter describing a pulse waveform, but does not include a single pulse duration Tₖ₍ₗ₎. Usually, as a fixed parameter, Tₖ₍ₗ₎ does not participate in an optimization process. That is, for different quantum tasks, Tₖ₍ₗ₎ in the above solution is constant, which leads to lack of flexibility of the solution. Therefore, there is still much room for improvement in the problem of optimizing the pulse duration. Besides, in the above solution, if the pulse duration is set unreasonably, pulses which are very small in pulse amplitude but very long in duration or very large in pulse amplitude but very short in duration may occur, whereas these pulses will influence the efficiency during the experiment.

Therefore, in the method according to the present disclosure, the pulse duration is considered in the optimization process by determining a proportional relationship between the single pulse duration and the pulse amplitude, so that the shape of the pulses is effectively constrained, and the difficulty of pulse generation in a real quantum computer is reduced.

According to some embodiments, as shown above with reference to the formula (2), the pulse enveloping may be Gaussian pulse enveloping, and the pulse enveloping parameters include the pulse amplitude, a pulse center position and a standard deviation. Therefore, determining the corresponding relationship between the pulse enveloping parameters and the single pulse duration, and determining the parameter to be optimized based on the corresponding relationship may include: determine the pulse center position and the standard deviation based on the single pulse duration; and determine a corresponding relationship between the pulse amplitude and the single pulse duration to determine the parameter to be optimized based on the corresponding relationship.

In some examples, in order to control a degree of freedom during pulse optimization, the pulse amplitude Aₖ₍ₗ₎^{x(y)} in the formula (2) may be only selected as the pulse parameter to be optimized, and a center position τₖ₍ₗ₎^{x(y)} and a standard deviation σₖ₍ₗ₎^{x(y)} are fixed. For example, the relationship between the center position τₖ₍ₗ₎^{x(y)} and the single pulse duration Tₖ₍ₗ₎ and relationship between the standard deviation σₖ₍ₗ₎^{x(y)} and the single pulse duration Tₖ₍ₗ₎ may be determined according to a formula (6) and a formula (7) respectively.

$${τ}_{k ( l )}^{x ( y )} = \frac{1}{2} {T}_{k ( l )} \qquad Formula ( 6 )$$

$${σ}_{k ( l )}^{x ( y )} = \frac{1}{7} {T}_{k ( l )} \qquad Formula ( 7 )$$

where Tₖ₍ₗ₎ is the single pulse duration, and coefficients in the formula (6) and the formula (7) are merely exemplary and may be adjusted according to actual conditions, which are not limited here.

According to some embodiments, the corresponding relationship between the single pulse duration Tₖ₍ₗ₎ and the pulse amplitude Aₖ₍ₗ₎^{x(y)} may be further determined through a formula (8) and a formula (9):

$${T}_{k ( l )} = \vert \frac{{A}_{k ( l )}^{x ( y )}}{{C}_{1}} \vert + {C}_{2} \qquad Formula ( 8 )$$

$${C}_{1} , {C}_{2} > 0 \qquad Formula ( 9 )$$

where C₁ and C₂ are two adjustable hyper-parameters. C₁ decides a steep degree (i.e., a rising speed of an amplitude) of the shape of the pulses, while C₂ decides a shortest duration of the pulses. Therefore, it can be seen that C₁ decides the relationship between the single pulse duration and the pulse amplitude, and also fixes the shape of the pulses to a certain extent. If a proper C₁ is selected, it can be ensured that the shape of the Gaussian pulses is relatively regular, and thus it is easier to realize in experiments. In the method according to the present disclosure, the impact of the single pulse duration Tₖ₍ₗ₎ is considered, and thus a total pulse duration may be dynamically adjusted through parameter optimization to be as short as possible.

According to some embodiments, the method according to the present disclosure may further include: in response to including at least two channels, pulses are alternately generated in the at least two channels based on the current pulse number.

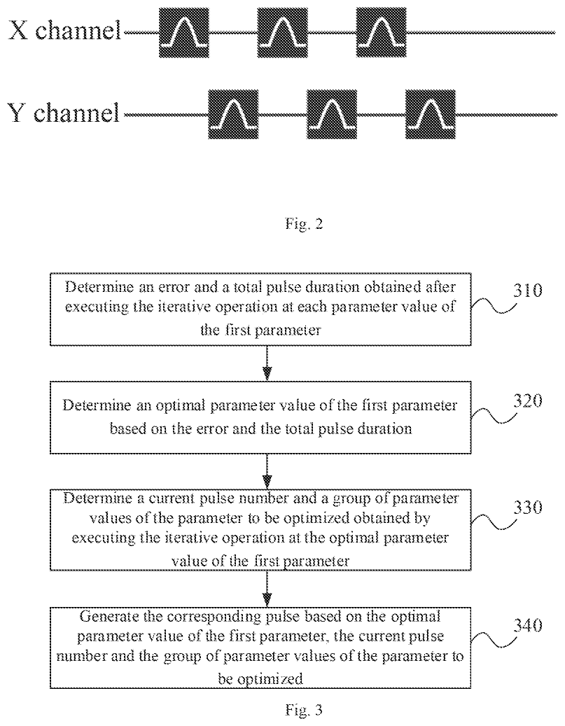

Usually, in a process of determining the pulse parameters for implementing the quantum gate, the pulse number on each channel and channels corresponding to the pulses need to be fixed. In the embodiment of the method according to the present disclosure, in order to improve the flexibility of the method, the pulse number on each channel may be not fixed and is set as a dynamically-adjustable variable, and a maximum value of the pulse numbers is set to be N. Therefore, at the beginning of a program, a total pulse number may be initialized (for example, the total pulse number starts from 1 and starts at the X channel), namely the current pulse number. If the error of the quantum gate after iterative optimization is less than the preset error tolerance or the current total pulse number has been larger than the set maximum value of the pulse numbers already, the program is ended. However, if the error of the quantum gate after iterative optimization is still greater than the preset error tolerance and the current total pulse number is less than the set maximum value of the pulse numbers, one pulse is added, and optimization is performed again. Here, the pulses may be applied to the X and Y channels alternately, and as shown in FIG. 2, a schematic diagram of a pulse circuit with the pulse number being 6 is shown.

The fidelity of the quantum gate may serve as a key performance index of compiling quality. The height of the fidelity of the quantum gate decides an implementation effect of a quantum task, so improving the fidelity of the quantum gate becomes a very important objective in a quantum control technology. Therefore, in some embodiments, the fidelity may be used to measure an error or distance between quantum gates. Of course, it should be understood that other methods or algorithms that may be used to measure the error or distance between the quantum gates are also possible, including but not limited to a trace distance and an F norm, which are not limited here.

According to some embodiments, the parameter to be optimized may include a first parameter and a second parameter. Therefore, the method 100 according to the present disclosure may further include: determine one or more parameter values of the first parameter to respectively execute the iterative operation at each parameter value of the first parameter. It should be noticed that the second parameter is the parameter to be optimized in the iterative operation.

As described above, C₁ may be used as the first parameter, and the pulse amplitude Aₖ₍ₗ₎^{x(y)} is used as the parameter to be optimized in the iterative operation. In an example, the parameter C₂ may be fixed, and a value range of C₁ is specified, so as to perform scanning within the value range (i.e., optimized as an external variable). That is, C₁ is optimized as a hyper-parameter, and is completely separated from optimization of the pulse parameters, that is, before each time of iterative operation, a value of C₁ is fixed, and then the pulse parameters are optimized under this condition; and a value of C₁ is changed to another value, and the iterative operation is performed again until all preset values are obtained within the preset value range of C₁.

According to some embodiments, as shown in FIG. 3, generating the corresponding pulse based on the current pulse number and the group of parameter values of the parameter to be optimized obtained after the iterative operation includes: obtain an error and a total pulse duration obtained after executing the iterative operation at each parameter value of the first parameter (step 310); determine an optimal parameter value of the first parameter based on the error and the total pulse duration (step 320); determine a current pulse number and a group of parameter values of the parameter to be optimized obtained by executing the iterative operation at the optimal parameter value of the first parameter (step 330); and generate the corresponding pulse based on the optimal parameter value of the first parameter, the current pulse number and the group of parameter values of the parameter to be optimized (step 340).

In one embodiment according to the present disclosure, a three-energy-level superconducting quantum bit is modeled first, and the quantum system defined by the Hamiltonian in the formula (1) is used here. Exemplarily, the discord intensity of the superconducting quantum bit is set as α_{q}=−0.33×2π GHz. A U3 quantum gate is randomly generated as the target quantum gate:

U3(θ=0.9933716,ϕ=5.03114766,λ=3.01783983) Formula (10)

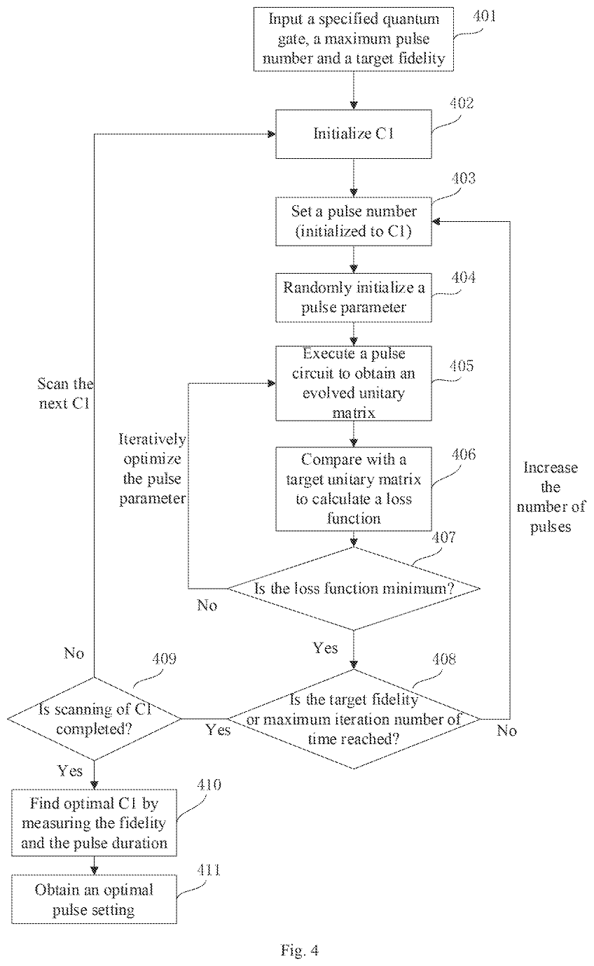

FIG. 4 shows a flow diagram of a pulse parameter determining method in the current embodiment. As shown in FIG. 4, first, a specified quantum gate, a maximum pulse number and a target fidelity are determined (step 401). Then, the corresponding relationship between the pulse enveloping parameter and the single pulse duration can be determined according to the formulas (6) to (9). In an example, C₂ may be fixedly set as 3.0 according to the formula (8), and then 10 points are equidistantly selected from 0.01≥C₁≥0.10 to be scanned (step 402). The current pulse number is set to start from 1 (step 403). In an example, a pulse parameter may be randomly initialized (step 404). A pulse circuit is executed based on the pulse parameter to obtain an evolved unitary matrix (step 405). The obtained evolved unitary matrix is compared with a target unitary matrix, and the fidelity is calculated based on a loss function (step 406). After the loss function is set, the pulse amplitude Aₖ₍ₗ₎^{x(y)} is optimized. Whether the loss function has been the minimum is judged (step 407), and if no, the pulse parameter is iteratively optimized through an optimization algorithm (step 407, “No”). If the loss function has been the minimum (step 407, “Yes”), whether the fidelity has reached a target fidelity (e.g., set to be 0.0003) or whether the pulse number has reached the set maximum pulse number (e.g., set to be 4) is judged (step 408), and if yes, this cycle is ended (step 408, “Yes”). Whether all values of C₁ have been scanned is judged (step 409), and if no, the next value of continues to be scanned; and if the fidelity does not reach the target fidelity and the pulse number does not reach the set maximum pulse number neither (step 408, “No”), one pulse is added to continue iteration to optimize the pulse parameter. After all the values of C₁ are scanned, an optimal value of C₁ is determined by measuring the fidelity and a pulse duration (step 410) to obtain an optimal pulse parameter setting based on the optimal C₁(step 411). Whether the quantum gates meet a corresponding fidelity requirement may be judged by obtaining the corresponding fidelity. As shown, Table 1 shows total pulse durations t_{g} and corresponding distortions obtained by performing an optimization operation under each value of C₁.

TABLE 1

| C1 | t_{g}(ns) | Distortion |
|---|---|---|
| 0.01 | 62.88973186561621 | 1.0776225123354521e−07 |
| 0.02 | 46.3150608996611 | 9.12831953470139e−07 |
| 0.03 | 39.00074648068719 | 1.5606953091995557e−05 |
| 0.04 | 34.64745447981032 | 8.041684951243244e−05 |
| 0.05 | 31.680216425083902 | 8.057591426424704e−05 |
| 0.06 | 24.0011804574133 | 0.29420386053094616 |
| 0.07 | 28.999975684835725 | 0.06759744193332984 |
| 0.08 | 43.99886908295048 | 0.0004278678372359179 |
| 0.09 | 38.000175037408276 | 0.0009871222780023503 |
| 0.10 | 29.307151626231807 | 0.0006729465275425728 |

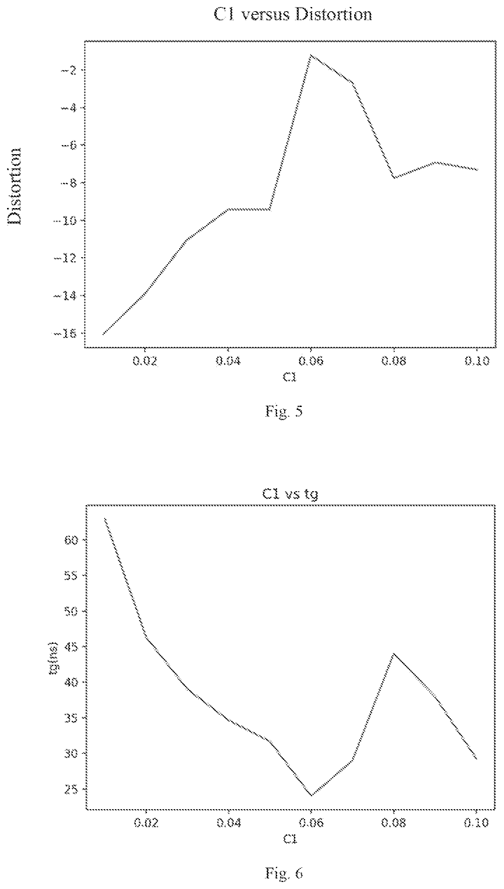

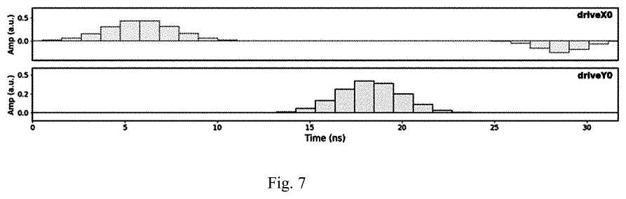

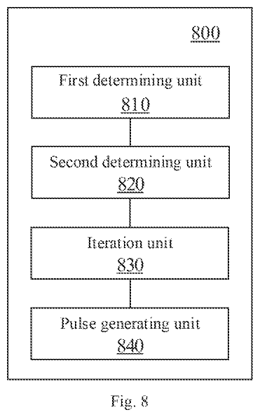

Therefore, the optimal parameter value of the first parameter may be determined based on the obtained distortions and total pulse durations, namely the value of C₁. In an example, after C₁ and the distortion are processed, such as taking a logarithm, the line chart shown in FIG. 5 may be obtained. C₁ and the total pulse duration t₉ are processed to obtain the line chart shown in FIG. 6. After the total pulse duration t_{g} and the distortion, C₁=0.05 may be selected as an optimal parameter value. FIG. 7 shows a pulse sequence corresponding to the optimal parameter value.

It can be understood that other quantum gates (e.g., a multi-quantum-bit quantum gate) and pulse enveloping based on other functions are similar to the above description, and are not repeated here.

Through multiple tests, it can be found that compared with a general pulse generation method, the method according to the embodiment of the present disclosure can shorten the pulse duration by 18%, and can reduce the distortion by 32% at the same time. The method according to the embodiment of the present disclosure can greatly reduce the pulse time in the case of the lower fidelity, such that the quantum gate is more efficient on a real machine.

According to an embodiment of the present disclosure, as shown in FIG. 8, a pulse-based quantum gate implementation apparatus 800 is further provided, including: a first determining unit 810, configured to determine a corresponding relationship between a pulse enveloping parameter and a single pulse duration, and determine a parameter to be optimized based on the corresponding relationship; a second determining unit 820, configured to determine a maximum pulse number, an initialized current pulse number and a preset error tolerance, wherein the initialized current pulse number is less than the maximum pulse number; an iteration unit 830, configured to execute a following iterative operation, until a pulse number reaches the maximum pulse number or an error of a quantum gate to be implemented is not greater than the error tolerance: initializing, based on the current pulse number, to obtain a group of parameter values of the parameter to be optimized, wherein the group of parameter values corresponding to the current pulse number; determining a quantum gate matrix to be implemented through a Schrodinger equation based on the current pulse number and the group of parameter values; determining a value of a loss function based on the quantum gate matrix to be implemented and a target quantum gate matrix; and adjusting the group of parameter values of the parameter to be optimized to minimize the value of the loss function; determining a quantum gate matrix to be implemented obtained after minimizing the value of the loss function and calculating an error between the quantum gate matrix to be implemented and the target quantum gate matrix; and in response to determining that the current pulse number is less than the maximum pulse number and the error is greater than the error tolerance, adding one to the current pulse number; and a pulse generating unit 840, configured to, based on the current pulse number and the group of parameter values of the parameter to be optimized obtained after the iterative operation, generate a corresponding pulse to implement a quantum gate.

Here, operations of the above units 810 to 840 of the pulse-based quantum gate implementation apparatus 800 are respectively similar to the operations of steps 110 to 140 described above, and are not repeated here.

According to an embodiment of the present disclosure, an electronic device, a readable storage medium and a computer program product are further provided.

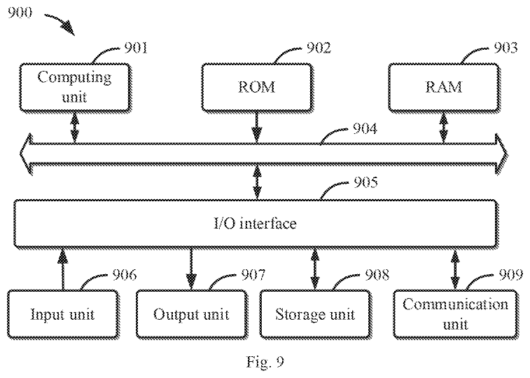

Referring to FIG. 9, a structural block diagram of an electronic device 900 that may serve as a server or a client of the present disclosure will now be described, and it is an example of a hardware device that may be applied to various aspects of the present disclosure. The electronic device is intended to represent various forms of digital electronic computer devices, such as, a laptop computer, a desktop computer, a workstation, a personal digital assistant, a server, a blade server, a mainframe computer, and other suitable computers. The electronic device may further represent various forms of mobile apparatuses, such as, personal digital processing, a cell phone, a smart phone, a wearable device and other similar computing apparatuses. The components shown herein, their connections and relationships, and their functions are merely used as examples, and are not intended to limit the implementations of the present disclosure described and/or required herein.

As shown in FIG. 9, the device 900 includes a computing unit 901 that may perform various appropriate actions and processing according to computer programs stored in a read-only memory (ROM) 902 or computer programs loaded from a storage unit 908 into a random access memory (RAM) 903. In RAM 903, various programs and data required for operations of device 900 may further be stored. The computing unit 901, the ROM 902 and the RAM 903 are connected to each other through a bus 904. An input/output (I/O) interface 905 is also connected to the bus 904.

A plurality of components in the device 900 are connected to the I/O interface 905, including: an input unit 906, an output unit 907, a storage unit 908 and a communication unit 909. The input unit 906 may be any type of device capable of inputting information to the device 900. The input unit 906 may receive input digital or character information and generate key signal input related to user settings and/or function control of the electronic device, and may include but not limited to a mouse, a keyboard, a touch screen, a trackpad, a trackball, a joystick, a microphone and/or a remote control. The output unit 907 may be any type of device capable of presenting information, and may include but not limited to a display, a speaker, a video/audio output terminal, a vibrator and/or a printer. The storage unit 908 may include but not limited to a magnetic disk and an optical disk. The communication unit 909 allows the device 900 to exchange information/data with other devices through computer networks such as the Internet and/or various telecommunication networks, and may include but not limited to a modem, a network card, an infrared communication device, a wireless communication transceiver and/or a chipset, such as a Bluetooth™ device, a 1302.11 device, a WiFi device, a WiMax device, a cellular communication device and/or the like.

The computing unit 901 may be various general-purpose and/or special-purpose processing components with processing and computing capabilities. Some examples of the computing unit 901 include but not limited to a central processing unit (CPU), a graphics processing unit (GPU), various dedicated artificial intelligence (AI) computing chips, various computing units running machine learning model algorithms, a digital signal processor (DSP), and any appropriate processor, controller, microcontroller, etc. The computing unit 901 performs various methods and processing described above, such as the method 100. For example, in some embodiments, the method 100 may be implemented as a computer software program that is tangibly included in a machine-readable medium such as the storage unit 908. In some embodiments, part of or all of computer programs may be loaded into and/or installed onto the device 900 via the ROM 902 and/or the communication unit 909. When the computer programs are loaded into the RAM 903 and executed by the computing unit 901, one or more steps of the method 100 described above may be performed. Alternatively, in other embodiments, the computing unit 901 may be configured to perform the method 100 in any other suitable manner (for example, by means of firmware).

Various implementations of the systems and technologies described above in this paper may be implemented in a digital electronic circuit system, an integrated circuit system, a field programmable gate array (FPGA), an application specific integrated circuit (ASIC), an application specific standard part (ASSP), a system on chip (SOC), a load programmable logic device (CPLD), computer hardware, firmware, software and/or their combinations. These various implementations may include: being implemented in one or more computer programs, wherein the one or more computer programs may be executed and/or interpreted on a programmable system including at least one programmable processor, and the programmable processor may be a special-purpose or general-purpose programmable processor, and may receive data and instructions from a storage system, at least one input apparatus, and at least one output apparatus, and transmit the data and the instructions to the storage system, the at least one input apparatus, and the at least one output apparatus.

Program codes for implementing the methods of the present disclosure may be written in any combination of one or more programming languages. These program codes may be provided to processors or controllers of a general-purpose computer, a special-purpose computer or other programmable data processing apparatuses, so that when executed by the processors or controllers, the program codes enable the functions/operations specified in the flow diagrams and/or block diagrams to be implemented. The program codes may be executed completely on a machine, partially on the machine, partially on the machine and partially on a remote machine as a separate software package, or completely on the remote machine or server.

In the context of the present disclosure, a machine readable medium may be a tangible medium that may contain or store a program for use by or in connection with an instruction execution system, apparatus or device. The machine readable medium may be a machine readable signal medium or a machine readable storage medium. The machine readable medium may include but not limited to an electronic, magnetic, optical, electromagnetic, infrared, or semiconductor system, apparatus or device, or any suitable combination of the above contents. More specific examples of the machine readable storage medium will include electrical connections based on one or more lines, a portable computer disk, a hard disk, a random access memory (RAM), a read only memory (ROM), an erasable programmable read only memory (EPROM or flash memory), an optical fiber, a portable compact disk read only memory (CD-ROM), an optical storage device, a magnetic storage device, or any suitable combination of the above contents.

In order to provide interactions with users, the systems and techniques described herein may be implemented on a computer, and the computer has: a display apparatus for displaying information to the users (e.g., a CRT (cathode ray tube) or LCD (liquid crystal display) monitor); and a keyboard and a pointing device (e.g., a mouse or trackball), through which the users may provide input to the computer. Other types of apparatuses may further be used to provide interactions with users; for example, feedback provided to the users may be any form of sensory feedback (e.g., visual feedback, auditory feedback, or tactile feedback); an input from the users may be received in any form (including acoustic input, voice input or tactile input).

The systems and techniques described herein may be implemented in a computing system including background components (e.g., as a data server), or a computing system including middleware components (e.g., an application server) or a computing system including front-end components (e.g., a user computer with a graphical user interface or a web browser through which a user may interact with the implementations of the systems and technologies described herein), or a computing system including any combination of such background components, middleware components, or front-end components. The components of the system may be interconnected by digital data communication (e.g., a communication network) in any form or medium. Examples of the communication network include: a local area network (LAN), a wide area network (WAN) and the Internet.

A computer system may include a client and a server. The client and the server are generally far away from each other and usually interact through a communication network. The relationship between the client and the server is generated by computer programs running on the corresponding computer and having a client-server relationship with each other. The server may be a cloud server, and may also be a server of a distributed system, or a server combined with a block chain.

It should be understood that the various forms of processes shown above may be used to reorder, add, or delete steps. For example, the steps recorded in the present disclosure may be performed in parallel, sequentially or in different orders, as long as the desired results of the technical solution disclosed by the present disclosure can be achieved, which is not limited herein.

Although the embodiments or examples of the present disclosure have been described with reference to the accompanying drawings, it should be understood that the above methods, systems and devices are only exemplary embodiments or examples, and the scope of the present invention is not limited by these embodiments or examples, but only by the authorized claims and their equivalent scope. Various elements in the embodiments or examples may be omitted or replaced by their equivalent elements. In addition, the steps may be performed in an order different from that described in the present disclosure. Further, various elements in the embodiments or examples may be combined in various ways. It is important that as technology evolves, many of the elements described herein may be replaced by equivalent elements that appear after the present disclosure.

1. A quantum gate implementation method for facilitating quantum computing, comprising:
determining a corresponding relationship between a pulse enveloping parameter and a single pulse duration, and determining a parameter to be optimized based on the corresponding relationship;
determining a maximum pulse number, an initialized current pulse number and a preset error tolerance, wherein the initialized current pulse number is less than the maximum pulse number;
executing an iterative operation, until a pulse number reaches the maximum pulse number or an error of a quantum gate to be implemented is not greater than the preset error tolerance, the iterative operation including:
obtaining, based on the current pulse number, a group of parameter values of the parameter to be optimized, wherein the group of parameter values corresponds to the current pulse number;
determining a quantum gate matrix to be implemented based on the current pulse number and the group of parameter values;
determining a value of a loss function based on the quantum gate matrix to be implemented and a target quantum gate matrix;
adjusting the group of parameter values of the parameter to be optimized to minimize the value of the loss function;
determining a quantum gate matrix to be implemented obtained after minimizing the value of the loss function and calculating an error between the quantum gate matrix to be implemented and the target quantum gate matrix; and
in response to determining that the current pulse number is less than the maximum pulse number and the error is greater than the error tolerance, adding one to the current pulse number; and
based on the current pulse number and the group of parameter values of the parameter to be optimized obtained after the iterative operation, generating a corresponding pulse to implement a quantum gate.

2. The method of claim 1, wherein the parameter to be optimized comprises a first parameter and a second parameter, the method further comprising:
determining one or more parameter values of the first parameter to respectively execute the iterative operation at each of the one or more parameter values, wherein, the second parameter is the parameter to be optimized in the iterative operation.

3. The method of claim 2, wherein, the generating the corresponding pulse comprises:
determining an error and a total pulse duration obtained after executing the iterative operation at each of the one or more parameter values;
determining an optimal parameter value of the first parameter based on the error and the total pulse duration;
determining a current pulse number and a group of parameter values of the parameter to be optimized obtained by executing the iterative operation at the optimal parameter value of the first parameter; and
generating the corresponding pulse based on the optimal parameter value of the first parameter, the current pulse number and the group of parameter values of the parameter to be optimized.

4. The method of claim 1, wherein, the target quantum gate matrix for a single quantum bit is determined based on a following formula:
$${U}_{Goal} ( θ , ϕ , λ ) = [ \begin{matrix}cos ( \frac{θ}{2} ) & - {e}^{i λ} sin ( \frac{θ}{2} ) \\ {e}^{i ϕ} sin ( \frac{θ}{2} ) & {e}^{i ( ϕ + λ )} cos ( \frac{θ}{2} )\end{matrix} ]$$
wherein, {θ, ϕ, λ} represent parameters of the target quantum gate matrix.

5. The method of claim 1, wherein, the loss function is determined based on a following formula:
$$g ( \overline{α} ) = 1 - \frac{1}{2} \vert Tr ( {U}_{Goal}^{†} {U}_{Real} ( \overline{α} ) ) \vert$$
wherein, α̅ represents the group of parameter values of the parameter to be optimized in the iterative operation, U_{Real}(α̅) represents the quantum gate matrix to be implemented, U_{Goal}^{†} represents an inverse of the target quantum gate matrix, and Tr( ) represents a trace of a matrix.

6. The method of claim 1, wherein, the adjusting of the group of parameter values of the parameter to be optimized to minimize the value of the loss function comprises:
adjusting the group of parameter values of the parameter to be optimized through an optimization algorithm to minimize the value of the loss function, wherein the optimization algorithm comprises any one of the following: a gradient descent method, a newton method, a conjugate gradient method and a heuristic method.

7. The method of claim 1, wherein a pulse enveloping associated with the pulse enveloping parameter comprises Gaussian pulse enveloping, and the pulse enveloping parameter comprises a pulse amplitude, a pulse center position and a standard deviation, wherein,
the determining of the corresponding relationship between the pulse enveloping parameter and the single pulse duration, and the determining of the parameter to be optimized based on the corresponding relationship comprise:
determining the pulse center position and the standard deviation based on the single pulse duration; and
determining a corresponding relationship between the pulse amplitude and the single pulse duration to determine the parameter to be optimized based on the corresponding relationship.

8. The method of claim 7, wherein the corresponding relationship between the pulse amplitude and the single pulse duration is determined based on a following formula:
$${T}_{k ( l )} = \vert \frac{{A}_{k ( l )}^{x ( y )}}{{C}_{1}} \vert + {C}_{2}$$
wherein, Tₖ₍ₗ₎ represents the single pulse duration, Aₖ₍ₗ₎^{x(y)} represents the pulse amplitude, and C₁ and C₂ represent hyper-parameters, wherein C₁, C₂>0.

9. The method of claim 1, further comprising: in response to comprising at least two channels, alternately generating pulses in the at least two channels based on the current pulse number.

10. An electronic device, comprising:
a memory storing one or more programs configured to be executed by one or more processors, the one or more programs including instructions for causing the electronic device to perform operations comprising:
determining a corresponding relationship between a pulse enveloping parameter and a single pulse duration, and determining a parameter to be optimized based on the corresponding relationship;
determining a maximum pulse number, an initialized current pulse number and a preset error tolerance, wherein the initialized current pulse number is less than the maximum pulse number;
executing an iterative operation, until a pulse number reaches the maximum pulse number or an error of a quantum gate to be implemented is not greater than the preset error tolerance, the iterative operation including:
obtaining, based on the current pulse number, a group of parameter values of the parameter to be optimized, wherein the group of parameter values corresponding to the current pulse number;
determining a quantum gate matrix to be implemented based on the current pulse number and the group of parameter values;
determining a value of a loss function based on the quantum gate matrix to be implemented and a target quantum gate matrix;
adjusting the group of parameter values of the parameter to be optimized to minimize the value of the loss function;
determining a quantum gate matrix to be implemented obtained after minimizing the value of the loss function and calculating an error between the quantum gate matrix to be implemented and the target quantum gate matrix; and
in response to determining that the current pulse number is less than the maximum pulse number and the error is greater than the error tolerance, adding one to the current pulse number; and
based on the current pulse number and the group of parameter values of the parameter to be optimized obtained after the iterative operation, generating a corresponding pulse to implement a quantum gate.

11. The electronic device of claim 10, wherein the parameter to be optimized comprises a first parameter and a second parameter, the operations further comprising:
determining one or more parameter values of the first parameter to respectively execute the iterative operation at each of the one or more parameter values, wherein, the second parameter is the parameter to be optimized in the iterative operation.

12. The electronic device of claim 11, wherein, the generating the corresponding pulse comprises:
determining an error and a total pulse duration obtained after executing the iterative operation at each of the one or more parameter values;
determining an optimal parameter value of the first parameter based on the error and the total pulse duration;
determining a current pulse number and a group of parameter values of the parameter to be optimized obtained by executing the iterative operation at the optimal parameter value of the first parameter; and
generating the corresponding pulse based on the optimal parameter value of the first parameter, the current pulse number and the group of parameter values of the parameter to be optimized.

13. The electronic device of claim 10, wherein, the target quantum gate matrix for a single quantum bit is determined based on a following formula:
$${U}_{Goal} ( θ , ϕ , λ ) = [ \begin{matrix}cos ( \frac{θ}{2} ) & - {e}^{i λ} sin ( \frac{θ}{2} ) \\ {e}^{i ϕ} sin ( \frac{θ}{2} ) & {e}^{i ( ϕ + λ )} cos ( \frac{θ}{2} )\end{matrix} ]$$
wherein, {θ, ϕ, λ} represents parameters of the target quantum gate matrix.

14. The electronic device of claim 10, wherein the loss function is determined based on a following formula:
$$g ( \overline{α} ) = 1 - \frac{1}{2} \vert Tr ( {U}_{Goal}^{†} {U}_{Real} ( \overline{α} ) ) \vert$$
wherein, α̅ represents the group of parameter values of the parameter to be optimized in the iterative operation, U_{Real}(α̅) represents the quantum gate matrix to be implemented, U_{Goal}^{†} represents an inverse of the target quantum gate matrix, and Tr( ) represents a trace of a matrix.

15. The electronic device of claim 10, wherein the adjusting of the group of parameter values of the parameter to be optimized to minimize the value of the loss function comprises:
adjusting the group of parameter values of the parameter to be optimized through an optimization algorithm to minimize the value of the loss function, wherein, the optimization algorithm comprises any one of the following: a gradient descent method, a newton method, a conjugate gradient method and a heuristic method.

16. The electronic device of claim 10, wherein, a pulse enveloping associated with the pulse enveloping parameter comprises Gaussian pulse enveloping, and the pulse enveloping parameter comprises a pulse amplitude, a pulse center position and a standard deviation, wherein,
the determining of the corresponding relationship between the pulse enveloping parameter and the single pulse duration, and the determining of the parameter to be optimized based on the corresponding relationship comprise:
determining the pulse center position and the standard deviation based on the single pulse duration; and
determining a corresponding relationship between the pulse amplitude and the single pulse duration to determine the parameter to be optimized based on the corresponding relationship.

17. The electronic device of claim 16, wherein, the corresponding relationship between the pulse amplitude and the single pulse duration is determined based on a following formula:
$${T}_{k ( l )} = \vert \frac{{A}_{k ( l )}^{x ( y )}}{{C}_{1}} \vert + {C}_{2}$$
wherein, Tₖ₍ₗ₎ represents the single pulse duration, Aₖ₍ₗ₎^{x(y)} represents the pulse amplitude, and C₁ and C₂ represent hyper-parameters, wherein C₁, C₂>0.

18. The electronic device of claim 10, the operations further comprising: in response to comprising at least two channels, alternately generating pulses in the at least two channels based on the current pulse number.

19. A non-transitory computer-readable storage medium that stores one or more programs comprising instructions that, when executed by one or more processors of a computing device, cause the computing device to implement operations comprising:
determining a corresponding relationship between a pulse enveloping parameter and a single pulse duration, and determining a parameter to be optimized based on the corresponding relationship;
determining a maximum pulse number, an initialized current pulse number and a preset error tolerance, wherein the initialized current pulse number is less than the maximum pulse number;
executing an iterative operation, until a pulse number reaches the maximum pulse number or an error of a quantum gate to be implemented is not greater than the preset error tolerance, the iterative operation including:
initializing, based on the current pulse number, to obtain a group of parameter values of the parameter to be optimized, wherein the group of parameter values corresponding to the current pulse number;
determining a quantum gate matrix to be implemented based on the current pulse number and the group of parameter values;
determining a value of a loss function based on the quantum gate matrix to be implemented and a target quantum gate matrix;
adjusting the group of parameter values of the parameter to be optimized to minimize the value of the loss function;
determining a quantum gate matrix to be implemented obtained after minimizing the value of the loss function and calculating an error between the quantum gate matrix to be implemented and the target quantum gate matrix; and
in response to determining that the current pulse number is less than the maximum pulse number and the error is greater than the error tolerance, adding one to the current pulse number; and
based on the current pulse number and the group of parameter values of the parameter to be optimized obtained after the iterative operation, generating a corresponding pulse to implement a quantum gate.

20. The non-transitory computer-readable storage medium of claim 19, wherein, the parameter to be optimized comprises a first parameter and a second parameter, the operations further comprising:
determining one or more parameter values of the first parameter to respectively execute the iterative operation at each of the one or more parameter values, wherein, the second parameter is the parameter to be optimized in the iterative operation.
